(19) United States
(12) Patent Application Publication
(10) Pub. No.: US 2012/0156523 A1
(43) Pub. Date: Jun. 21, 2012

(54) Perpendicular Magnetic Recording Medium And Method Of Manufacturing Same

(75) Inventors: TOMOKO SEKI, San Jose, CA (US); IWAO OKAMOTO, Singapore (SG)

(73) Assignee: WD MEDIA (SINGAPORE) PTE. LTD., Irvine, CA (US)

(21) Appl. No.: 13/153,275

(22) Filed: Jun. 3, 2011

(30) Foreign Application Priority Data
Jun. 3, 2010 (JP) 2010-127697

(51) Int. Cl. G11B 5/708; C23C 14/35; G11B 5/70

(52) U.S. Cl. 428/832.1; 428/832; 204/192.15

(57) ABSTRACT

[Summary]

[Problem] An object is to attain both reduction in size of magnetic particles and reduction in distance between magnetic particles to achieve a higher recording density and a higher SN ratio.

[Solution] A perpendicular magnetic recording medium according to the present invention is a perpendicular magnetic recording medium having a laminate film including at least a magnetic layer on a base plate, wherein the magnetic layer includes a magnetic material having a granular structure and a non-magnetic grain boundary including an inter-ceramic compound containing Mg.

### TECHNICAL FIELD

The present invention relates to a perpendicular magnetic recording medium installed in an HDD (hard disk drive) of a perpendicular magnetic recording type, or the like, and a method of manufacturing the same.

### BACKGROUND ART

With increase in capacity of information processing in recent years, various information recording technologies have been developed. In particular, the surface recording density of an HDD using a magnetic recording technology is continuously increasing at an annual rate of approximately 50% to 60%. Recently, an information recording capacity exceeding 320 gigabytes/platter with a 2.5-inch diameter of a magnetic recording medium for use in an HDD or the like has been demanded, and in order to satisfy such a demand, an information recording density exceeding 500 gigabytes/square inch is required to be realized.

In order to achieve high recording density in a magnetic recording medium for use in an HDD or the like, a perpendicular magnetic recording type has been suggested in recent years. In a perpendicular magnetic recording medium used for the perpendicular magnetic recording type, an easy axis of magnetization of a granular magnetic layer (magnetic layer having a granular structure) is adjusted so as to be oriented in a perpendicular direction with respect to a base plate surface. The perpendicular magnetic recording type is more suitable for increasing recording density than a conventional in-plane magnetic recording type, since the perpendicular magnetic recording type can suppress a so-called thermal fluctuation phenomenon that a recording signal is lost due to a superparamagnetic phenomenon impairing thermal stability of the recording signal.

In order to achieve increase in recording density so that a higher signal-noise ratio (SN ratio) is achieved, the number of magnetic particles existing per bit which is the smallest recording unit must be increased, and the size of a particle must be reduced. Therefore, in a magnetic layer (recording layer) of a perpendicular magnetic recording medium, magnetic particles are separated by a non-magnetic phase in order to reduce magnetic interaction between magnetic particles (for example, Patent Document 1)

### PRIOR ART DOCUMENT

### Patent Document

Patent Document 1: Japanese Unexamined Patent Application Publication No. 2006-024346

### SUMMARY OF THE INVENTION

### Problem to be Solved by the Invention

Regarding the separation of magnetic particles by the non-magnetic phase, the sizes of magnetic particles and the distance between magnetic particles affect the non-magnetic material used for the magnetic layer and the volume fraction thereof. Generally, as the volume fraction increases, the sizes of magnetic particles become small, but the region of the non-magnetic phase expands, and consequently the magnetic particle density is not caused to increase. In order to improve the density of magnetic particles, both reduction in size of magnetic particles and reduction in distance between magnetic particles are required.

The present invention has been made in view of these circumstances, and an object thereof is to provide a perpendicular magnetic recording medium that can attain both reduction in size of magnetic particles and reduction in distance between magnetic particles to achieve a higher recording density and a higher SNR, and a method of manufacturing the same.

### Means for Solving the Problem

A perpendicular magnetic recording medium of the present invention is a perpendicular magnetic recording medium having a laminate film including at least a magnetic layer on a base plate, wherein the magnetic layer includes a magnetic material having a granular structure and a non-magnetic grain boundary including an inter-ceramic compound containing Mg.

According to this configuration, since the magnetic layer includes the magnetic material having a granular structure and the non-magnetic grain boundary including an inter-ceramic compound containing Mg, both reduction in size of magnetic particles and reduction in distance between magnetic particles can be achieved. As a result, a perpendicular magnetic recording medium having such a magnetic layer can realize a higher recording density and a higher SN ratio.

Regarding the perpendicular magnetic recording medium of the present invention, it is preferred that the magnetic material be a CoCrPt alloy, and the inter-ceramic compound be one selected from a group consisting of Mg₂SiO₄, MgSiO₃, and MgTiO₃.

Regarding the perpendicular magnetic recording medium of the present invention, it is preferred that the magnetic layer be formed by sputtering with use of a target composed of a CoCrPt alloy and one selected from a group consisting of Mg₂SiO₄, MgSiO₃, and MgTiO₃.

Regarding the perpendicular magnetic recording medium of the present invention, it is preferred that the magnetic layer have 12 or more granular magnetic particles existing in a region corresponding to one bit, when viewed in a plane.

A method of manufacturing a perpendicular magnetic recording medium of the present invention is a method of manufacturing a perpendicular magnetic recording medium having a laminate film including at least a magnetic layer on a base plate, the method including forming the magnetic layer by sputtering with use of a target composed of a magnetic material having a granular structure and an inter-ceramic compound containing Mg.

According to this method, a magnetic layer having a magnetic material having a granular structure and a non-magnetic grain boundary including an inter-ceramic compound containing Mg can be formed. Thus, a perpendicular magnetic recording medium that can achieve a higher recording density and a higher SN ratio can be obtained.

Regarding the method of manufacturing a perpendicular magnetic recording medium of the present invention, it is preferred that the magnetic material is a CoCrPt alloy, and the inter-ceramic compound is one selected from a group consisting of Mg₂SiO₄, MgSiO₃, and MgTiO₃.

### Effects of the Invention

According to the present invention, since the magnetic layer has a non-magnetic grain boundary including an inter-ceramic compound containing Mg, both reduction in size of magnetic particles and reduction in distance between magnetic particles can be achieved. As a result, a higher recording density and a higher SN ratio can be realized.

### BRIEF DESCRIPTIONS OF THE DRAWINGS

FIG. 1 is a diagram for describing the configuration of a perpendicular magnetic recording medium according to an embodiment of the present invention; and

FIG. 2 is an equilibrium diagram of two or more kinds of oxides.

### EMBODIMENT OF THE INVENTION

An embodiment of a method of manufacturing a perpendicular magnetic recording medium according to the present invention will be described below.

### (Perpendicular Magnetic Recording Medium)

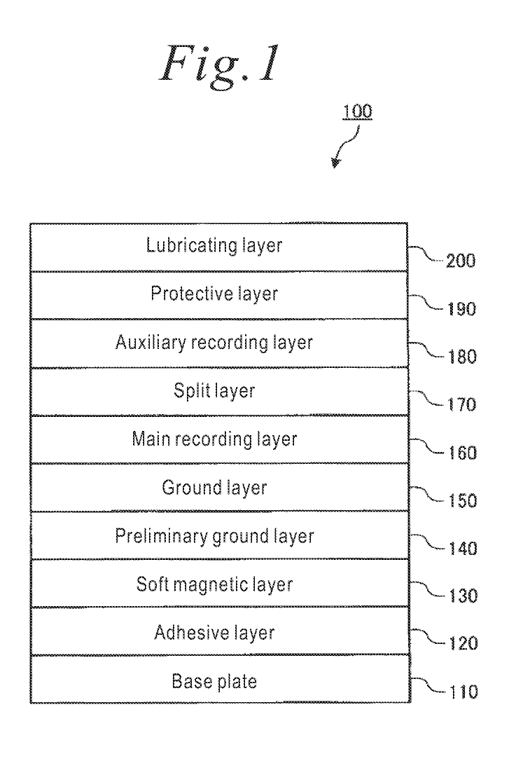

FIG. 1 is a diagram for describing the configuration of a perpendicular magnetic recording medium 100 according to an embodiment of the present invention. The perpendicular magnetic recording medium 100 shown in FIG. 1 has a laminate film including at least a magnetic layer on a base plate 110. The laminate film is mainly composed of an adhesive layer 120, a soft magnetic layer 130, a preliminary ground layer 140, a ground layer 150, a main recording layer 160, a split layer 170, an auxiliary recording layer 180, a protective layer 190, and a lubricating layer 200.

As the base plate 110, for example, a glass disk molded in a disk shape by direct-pressing amorphous aluminosilicate glass can be used. Note that the kind, size, thickness, and others of the glass disk are not particularly restricted. A material of the glass disk can be, for example, aluminosilicate glass, soda lime glass, soda aluminosilicate glass, aluminoborosilicate glass, borosilicate glass, quartz glass, chain silicate glass, or glass ceramic, such as crystallized glass. This glass disk is sequentially subjected to grinding, polishing, and chemical strengthening, thereby allowing a smooth non-magnetic base plate 110 made of a chemically-strengthened glass disk to be obtained.

On the base plate 110, the adhesive layer 120 to the auxiliary recording layer 180 are sequentially formed by DC magnetron sputtering, and the protective layer 190 can be formed by CVD. Thereafter, the lubricating layer 200 can be formed by dip coating. The configuration of each layer will be described below.

The adhesive layer 120 is formed in contact with the base plate 110, and provided with a function of increasing adhesion strength between the soft magnetic layer 130 formed thereon and the base plate 110. It is preferred that the adhesive layer 120 be a film of amorphous alloy, such as a CrTi-type amorphous alloy, a CoW-type amorphous alloy, a CrW-type amorphous alloy, a CrTa-type amorphous alloy, or a CrNb-type amorphous alloy. The film thickness of the adhesive layer 120 can be set, for example, in the range of approximately 2 nm to 20 nm. The adhesive layer 120 may be a single layer or may have a laminate structure.

The soft magnetic layer 130 acts to converge a writing magnetic field from the head when a signal is recorded in a perpendicular magnetic recording type, thereby supporting easy writing of a signal to a magnetic recording layer and density growth. As a soft magnetic material, not only a cobalt-type alloy, such as CoTaZr, but also a material that exhibits a soft magnetic property, such as an FeCo-type alloy, such as FeCoCrB, FeCoTaZr, or FeCoNiTaZr, or a NiFe-type alloy, can be used. The soft magnetic layer 130 can be configured to be provided with AFC (antiferro-magnetic exchange coupling) by interposing a spacer layer made of Ru approximately in the middle of the soft magnetic layer 130. This configuration can reduce perpendicular components of magnetization extremely, and thus noise generated from the soft magnetic layer 130 can be reduced. In the configuration of interposition of the spacer layer in the soft magnetic layer 130, the film thickness of the soft magnetic layer 130 can be set to about 0.3 nm to 0.9 nm for the spacer layer and about 10 nm to 50 nm for each of upper and lower layers made of soft magnetic material.

The preliminary ground layer 140 is provided with a function of promoting crystal orientation of the ground layer 150 formed thereon and a function of controlling a fine structure, such as a particle diameter. Though the preliminary ground layer 140 may have an hcp structure, it is preferred that the preliminary ground layer 140 have a face-centered cubic structure (fcc structure) in which a (111) face is oriented so as to be parallel to a main surface of the base plate 110. As a material of the preliminary ground layer 140, for example, Ni, Cu, Pt, Pd, Ru, Co, Hf, or an alloy containing these metals as a main component and added with one or more of V, Cr, Mo, W, Ta, and the like can be selected. Specifically, NiV, NiCr, NiTa, NiW, NiVCr, CuW, CuCr, or the like can be suitably selected. The film thickness of the preliminary ground layer 140 can be set in the range of about 1 nm to 20 nm. The preliminary ground layer 140 may also have a laminate structure.

The ground layer 150 has an hcp structure, is provided with a function of promoting crystal orientation of magnetic crystal grains in the hcp structure of the main recording layer 160 formed thereon, and a function of controlling a fine structure, such as a particle diameter, and serves as a so-called foundation for a granular structure of the main recording layer. Ru has the same hcp structure as Co, and has a crystal lattice space close to that of Co, and therefore Ru can successfully orient magnetic particles containing Co as a main component. Therefore, higher crystal orientation of the ground layer 150 can improve the crystal orientation of the main recording layer 160, and refinement of the particle diameters of the ground layer 150 can cause refinement of the particle diameters of the main recording layer. Though Ru is a typical material of the ground layer 150, a metal, such as Cr or Co, or an oxide can also be added to the ground layer 150. The film thickness of the ground layer 150 can be set to range from about 5 nm to 40 nm, for example.

The ground layer 150 may also have a two-layer structure by changing a gas pressure at a sputtering time. Specifically, by making the gas pressure of Ar higher when an upper side layer of the ground layer 150 is formed than when a lower side layer thereof is formed, the particle diameter of magnetic particles can be refined with the crystal orientation of the main recording layer 160 thereon kept well.

The main recording layer (magnetic layer) 160 includes a magnetic material having a granular structure and a non-magnetic grain boundary containing an inter-ceramic compound containing Mg. That is, the main recording layer (magnetic layer) 160 has a columnar granular structure in which a grain boundary is formed by segregation of non-magnetic substances containing an inter-ceramic compound as a main component around magnetic particles of a ferromagnetic body containing a CoCrPt-type alloy as a main component.

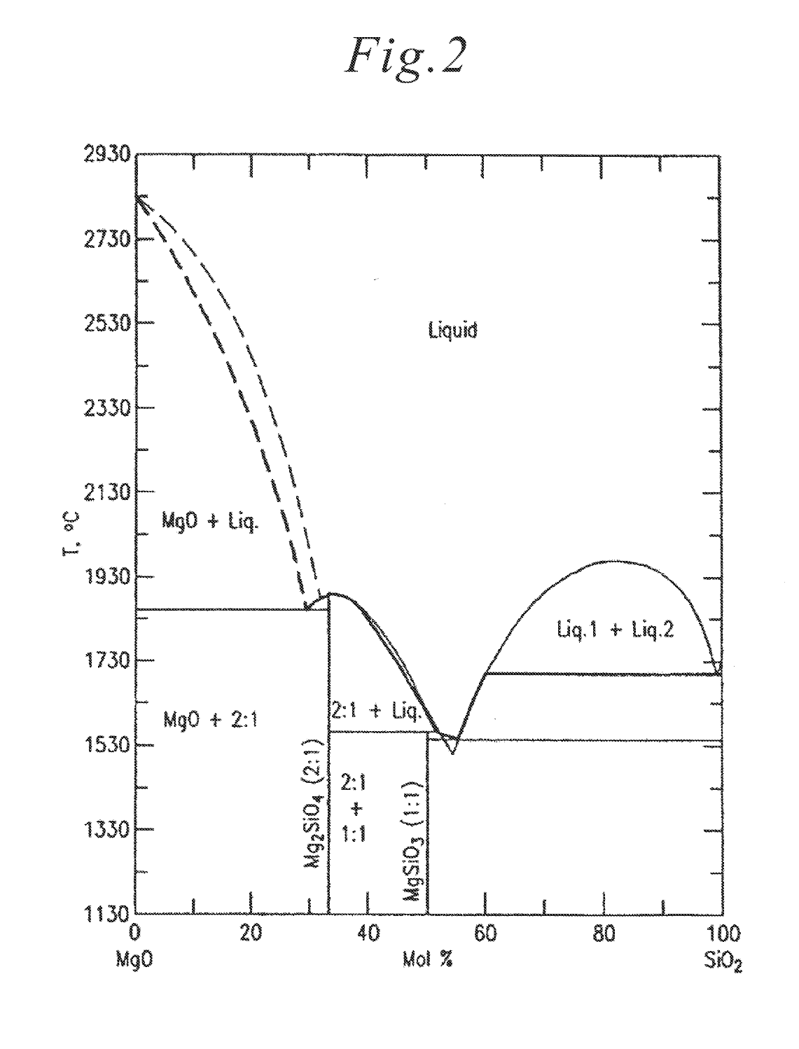

Here, for example, when a third oxide is formed, as shown in FIG. 2, on an equilibrium diagram composed of two or more types of oxides, the third oxide is referred to as the inter-ceramic compound. As the inter-ceramic compound, one selected from a group consisting of Mg₂SiO₄, MgSiO₃, and MgTiO₃ can be used. The main recording layer 160 thus configured is formed by sputtering with use of a target composed of a magnetic material having a granular structure and the inter-ceramic compound containing Mg. That is, it is formed by sputtering with use of a target composed of a CoCrPt alloy and one selected from a group consisting of Mg₂SiO₄, MgSiO₃, and MgTiO₃. Thus, a granular structure in which a grain boundary is formed due to segregation of Mg₂SiO₄, MgSiO₃, or MgTiO₃, which is a non-magnetic substance, around magnetic particles (grains) composed of a CoCrPt-type alloy and in which the magnetic particles are grown into columnar shape can be formed.

The main recording layer 160 thus formed has 12 or more granular magnetic particles existing in a region corresponding to one bit, when viewed in a plane. Therefore, both reduction in size of magnetic particles and reduction in distance between magnetic particles can be achieved. As a result, the perpendicular magnetic recording medium having the main recording layer (magnetic layer) 160 thus configured can achieve a higher recording density and a higher SN ratio.

Note that the substance used in the main recording layer 160 described above is an example, not a limitation. As the CoCrPt-type alloy, a substance obtained by adding at least one kind of B, ta, Cu, and the like in CoCrPt may be used.

The split layer 170 is provided between the main recording layer 160 and the auxiliary recording layer 180, and has a function of adjusting the strength of exchange coupling therebetween. Since this can adjust the strength of magnetic coupling between the main recording layer 160 and the auxiliary recording layer 180 and between adjacent magnetic particles in the main recording layer 160, it is possible to improve a recording and reproduction characteristic, such as an overwrite characteristic or an SNR characteristic while keeping a magnetostatic value, such as Hc or Hn that relate to an anti-thermal-fluctuation characteristic.

It is preferred that, in order to prevent inheritance of crystal orientation from lowering, the split layer 170 be a layer containing Ru or Co with an hcp structure as a main component. As a Ru-type material, other than Ru, a material obtained by adding another metal element, oxygen, or an oxide in Ru can be used. As a Co-type material, a CoCr alloy or the like can be used. Specifically, Ru, RuCr, RuCo, Ru—SiO₂, Ru—WO₃, Ru—TiO₂, CoCr, CoCr—SiO₂, CoCr—TiO₂, or the like can be used. Note that, though a non-magnetic material is generally used for the split layer 170, but the split layer 170 may have weak magnetism. Further, in order to obtain a good exchange coupling strength, it is preferred that the film thickness of the split layer 170 be in the range of 0.2 nm to 1.0 nm.

The auxiliary recording layer 180 is a magnetic layer magnetically approximately continuous in an in-plane direction of the main surface of the base plate. Since the auxiliary recording layer 180 has magnetic interaction (exchange coupling) with the main recording layer 160, it is possible to adjust a magnetostatic characteristic, such as a coercive force Hc or a reverse domain nucleation magnetic field Hn, which aims at improving the anti-thermal-fluctuation characteristic, the OW (overwrite) characteristic, and the SNR. As a material of the auxiliary recording layer 180, a CoCrPt-type alloy can be used, and further an additive, such as B, Ta, or Cu, may be added therein. Specifically, CoCrPt, CoCrPtB, CoCrPtTa, CoCrPtCu, CoCrPtCuB, or the like can be used. The film thickness of the auxiliary recording layer 180 can be set, for example, in the range of 3 nm to 10 nm.

Note that “magnetically continuous” means that magnetism is continuous without interruption. “Approximately continuous” means that, when seen as a whole, the auxiliary recording layer 180 does not have to be a single magnet and may have partially-discontinuous magnetism. That is, the auxiliary recording layer 180 is only required to have magnetism continuous over (so as to cover) a plurality of aggregates of magnetic particles. As long as this condition is satisfied, the auxiliary recording layer 180 may have a structure in which Cr is segregated, for example.

The protective layer 190 is a layer for protecting the perpendicular magnetic recording medium 100 from an impact from the magnetic head or corrosion. The protective layer 190 can be formed by forming a film containing carbon by CVD. A carbon film formed by CVD is preferred, since in general it is improved in film hardness as compared with one formed by sputtering, and therefore can protect the perpendicular magnetic recording medium 100 more effectively from the impact from the magnetic head. The film thickness of the protective layer 190 can be set, for example, in that range of 2 nm to 6 nm.

The lubricating layer 200 is formed to prevent the protective layer 190 from being damaged when the magnetic head comes in contact with the surface of the perpendicular magnetic recording medium 100. For example, the lubricating layer 200 can be formed by dip-coating PFPE (perfluoropolyether). The film thickness of the lubricating layer 200 can be set, for example, in the range of 0.5 nm to 2.0 nm.

Next, an example formed in order to clarify an effect of the present invention will be described.

### Example

A glass disk was formed by molding amorphous aluminosilicate glass in a disk shape by direct-pressing. This glass disk was sequentially subjected to grinding, polishing, and chemical strengthening, and thus a base plate which was a smooth non-magnetic disk base made of a chemically-strengthened glass disk was obtained. The base plate was a base plate for a 2.5-inch magnetic disk being 65 mm in diameter, 20 mm in inner diameter, and 0.8 mm in disk thickness. From observation of surface roughness of the base plate obtained with an AFM (atomic force microscope), it was confirmed that the base plate had a smooth surface with 2.18 nm in Rmax and 0.18 nm in Ra. Note that Rmax and Ra adhere to Japanese Industrial Standards (JIS).

Next, the adhesive layer 120, the soft magnetic layer 130, the preliminary ground layer 140, ground layer 150, the main recording layer 160, the split layer 170, and the auxiliary recording layer 180 were sequentially formed on the base plate 110 in an Ar atmosphere by DC magnetron sputtering with use of a vacuumed film forming device. Note that an Ar gas pressure at the film formation time was 0.6 Pa, unless otherwise described.

Specifically, as the adhesive layer 120, a 10 nm-thick Cr-50Ti film was formed. As the soft magnetic layer 130, 20 nm-thick 92(40Fe-60Co)-3Ta-5Zr films were formed with a 0.7 nm-thick Ru layer interposed therebetween. As the preliminary ground layer 140, an 8 nm-thick Ni-5W film was formed. As the ground layer 150, a 10 nm-thick Ru film was formed, and thereon a 10 nm-thick Ru was formed at an Ar gas pressure of 5 Pa. As the main recording layer 160, a 2 nm-thick 90(70Co-10Cr-20Pt)-10(Cr₂O₃) film was formed at an Ar gas pressure of 3 Pa, and thereon a 10 nm-thick 94(72Co-10Cr-18Pt)-6(Mg₂SiO₄) film was further formed at an Ar gas pressure of 3 Pa. As the split layer 170, a 0.3 nm-thick Ru film was formed. As the auxiliary recording layer 180, a 6 nm-thick 62Co-18Cr-15Pt-5B film was formed.

The protective layer 190 with a thickness of 4 nm was formed on the auxiliary recording layer 180 by using C₂H₄ by CVD, and a superficial layer thereof was subjected to nitriding treatment. Next, the lubricating layer 200 was formed to have a thickness of 1 nm by using PFPE (perfluoropolyether) by dip coating. In this manner, a perpendicular magnetic recording medium according to the example was manufactured.

### Comparative Example

A perpendicular magnetic recording medium of a comparative example was formed in the same manner as the example, except that, as the main recording layer 160, a 2 nm-thick 90(70Co-10Cr-20Pt)-10(Cr₂O₃) film was formed at an Ar gas pressure of 3 Pa, and thereon a 10 nm-thick 90(72Co-10Cr-18Pt)-10(SiO₂) film was further formed at an Ar gas pressure of 3 Pa.

The SNRs of the manufactured perpendicular magnetic recording medium of the example and the manufactured perpendicular magnetic recording medium of the comparative example were examined. The result is shown in the following table 1. Note that the recording and reproduction characteristics were measured with a recording density of 1500 kfci by using an R/W analyzer and a magnetic head for a perpendicular magnetic recording type that is provided with an SPT element on a recording side and a GMR element on a reproduction side. At that time, a floating height of the magnetic head was 10 nm.

TABLE 1

| | Non- | Particle counts | | SNR (ratio to |
|---|---|---|---|---|
| | magnetic | per 1 bit | | Comparative |
| | grain | in 500 GB | Particle size | Example) |
| | boundary | (number) | (nm) | (dB) |
| Example | Mg₂SiO₄ | 14 | 5.5 | +1.0 |
| Comparative | SiO₂ | 8 | 9 | 0 |
| Example | | | | |

As can be seen from Table 1, in the case (Example) where the non-magnetic grain boundary in the main recording layer was an inter-ceramic compound, the SNR was very favorable, as compared with in the case (Comparative Example) where the non-magnetic grain boundary in the main recording layer was an oxide. It is thought that this is because reduction in size of magnetic particles and reduction in distance between magnetic particles could be achieved. Therefore, it can be seen that the perpendicular magnetic recording medium of the present invention can achieve a higher recording density and a higher SN ratio.

The preferred embodiment of the present invention has been described above with reference to the appended drawings, but it goes without saying that the present invention is not limited to the embodiment. It is obvious that a person skilled in the art can arrive at various modifications or alterations within the scope of claims, and those are of course understood as belonging to the technical scope of the present invention.

### INDUSTRIAL APPLICABILITY

The present invention is applicable as a perpendicular magnetic recording medium installed in an HDD of a perpendicular magnetic recording type, or the like, and as a method of manufacturing the same.

### DESCRIPTIONS OF REFERENCE NUMERALS

100: Perpendicular magnetic recording medium
110: Base plate
120: Adhesive layer
130: Soft magnetic layer
140: Preliminary ground layer
150: Ground layer
160: Main recording layer
170: Split layer
180: Auxiliary recording layer
190: Protective layer
200: Lubricating layer

1. A perpendicular magnetic recording medium having a laminate film including at least a magnetic layer on a base plate, wherein the magnetic layer includes a magnetic material having a granular structure and a non-magnetic grain boundary including an inter-ceramic compound containing Mg.

2. The perpendicular magnetic recording medium according to claim 1, wherein the magnetic material is a CoCrPt alloy, and the inter-ceramic compound is one selected from a group consisting of Mg₂SiO₄, MgSiO₃, and MgTiO₃.

3. The perpendicular magnetic recording medium according to claim 2, wherein the magnetic layer is formed by sputtering with use of a target composed of a CoCrPt alloy and one selected from a group consisting of Mg₂SiO₄, MgSiO₃, and MgTiO₃.

4. The perpendicular magnetic recording medium according to any one of claims 1 to 3, wherein the magnetic layer has 12 or more granular magnetic particles existing in a region corresponding to one bit, when viewed in a plane.

5. A method of manufacturing a perpendicular magnetic recording medium having a laminate film including at least a magnetic layer on a base plate, the method comprising forming the magnetic layer by sputtering with use of a target composed of a magnetic material having a granular structure and an inter-ceramic compound containing Mg.

6. The method of manufacturing a perpendicular magnetic recording medium according to claim 5, wherein the magnetic material is a CoCrPt alloy, and the inter-ceramic compound is one selected from a group consisting of Mg₂SiO₄, MgSiO₃, and MgTiO₃.
